(19) United States
(12) Patent Application Publication
(10) Pub. No.: US 2026/0011587 A1
(43) Pub. Date: Jan. 8, 2026

(54) INFORMATION PROCESSING APPARATUS, INFORMATION PROCESSING METHOD, AND SUBSTRATE PROCESSING APPARATUS

(71) Applicant: Tokyo Electron Limited, Tokyo (JP)

(72) Inventors: Nobutoshi TERASAWA, Hokkaido (JP); Ryota AOI, Hokkaido (JP)

(21) Appl. No.: 19/255,446

(22) Filed: Jun. 30, 2025

(30) Foreign Application Priority Data
Jul. 3, 2024 (JP) 2024-107520

(51) Int. Cl. H01L 21/67

(52) U.S. Cl. CPC H01L 21/67253; H01L 21/67248

(57) ABSTRACT

An information processing apparatus including: an acquisition unit that acquires a process log for each execution of the same process including a plurality of process steps in one or more substrate processing apparatuses that execute the process according to a recipe; an analysis unit that compares, based on the process logs, step times taken for the same process step and analyzes a process step having time variation as time-variable step; and a display control unit that displays information related to the time-variable step.

### CROSS REFERENCES TO RELATED APPLICATIONS

This application is based on and claims priority from Japanese Patent Application No. 2024-107520, filed on Jul. 3, 2024, with the Japan Patent Office, the disclosure of which is incorporated herein in its entirety by reference.

### TECHNICAL FIELD

The present disclosure relates to an information processing apparatus, an information processing method, and a substrate processing apparatus.

### BACKGROUND

In the related art, a substrate processing apparatus monitors operational data and detects abnormalities during operation. In the meantime, it is important to reduce instances in which the operation of the substrate processing apparatus is stopped due to abnormality detection, so as to improve the productivity of the substrate processing apparatus. For example, Japanese Patent Laid-open Publication No. 2023-134074 proposes a technique in which, for example, an operator identifies the operating state of the substrate processing apparatus during operation and takes appropriate measures before an abnormality is detected.

### SUMMARY

An aspect of the present disclosure is an information processing apparatus. The information processing apparatus includes: an acquisition unit that acquires a process log for each execution of the same process including a plurality of process steps in one or more substrate processing apparatuses that execute the process according to a recipe; an analysis unit that compares, based on the process logs, step times taken for the same process step and analyzes a process step having time variation as time-variable step; and a display control unit that displays information related to the time-variable step.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 a configuration diagram illustrating a substrate processing system according to an embodiment.

FIG. 2 is a hardware configuration diagram illustrating an example of a computer.

FIG. 3 is a functional block diagram illustrating an example of an operator terminal according to the present embodiment.

FIG. 4 is a flowchart illustrating an example of a processing procedure for displaying information related to time-variable steps in the substrate processing system of the present embodiment.

FIG. 5 is a flowchart illustrating an example of the processing procedure of step S12.

FIG. 6 is a view illustrating an example of a screen image including information related to time-variable steps.

FIG. 7 is a view illustrating an example of a screen image including information related to time-variable steps.

FIG. 8 is a view illustrating an example of a screen image including information related to time-variable steps.

FIG. 9 is a view illustrating an example of a screen image including information related to time-variable steps.

### DETAILED DESCRIPTION

In the following detailed description, reference is made to the accompanying drawings, which form a part hereof. The illustrative embodiments described in the detailed description, drawings, and claims are not meant to be restricting. Other embodiments may be utilized, and other changes may be made without departing from the spirit or scope of the subject matter presented here.

Hereinafter, exemplary embodiments of the present disclosure will be described with reference to drawings.

### <System Configuration>

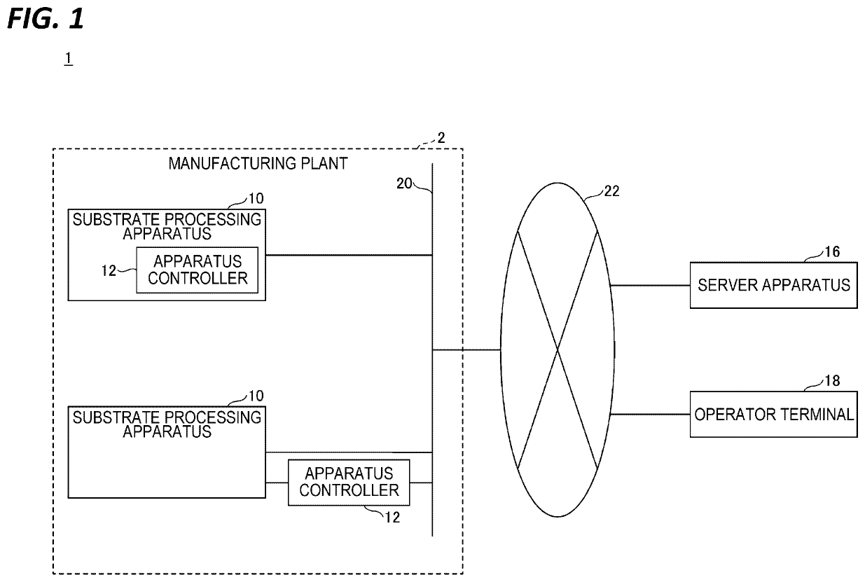

FIG. 1 is a configuration diagram illustrating an example of a substrate processing system 1 according to the present embodiment. The substrate processing system 1 illustrated in FIG. 1 includes a substrate processing apparatus 10, an apparatus controller 12, a server apparatus 16, and an operator terminal 18.

The substrate processing apparatus 10 and the apparatus controller 12 are installed in a manufacturing plant 2. The server apparatus 16 and the operator terminal 18 may be installed in the manufacturing plant 2 or outside the manufacturing plant 2. The operator terminal 18 is an information processing terminal operated by an operator, such as a person in charge of the apparatus or a person in charge of analysis, for the substrate processing apparatus 10 installed in the manufacturing plant 2. The operator terminal 18 may be, for example, a personal computer (PC) or a smartphone.

The substrate processing apparatus 10, the apparatus controller 12, the server apparatus 16, and the operator terminal 18 illustrated in FIG. 1 are communicably connected via networks 20 and 22 such as the Internet or a local area network (LAN).

The substrate processing apparatus 10 is an apparatus that performs processing such as film formation, etching, or ashing, and is configured to process a substrate such as, for example, a semiconductor wafer. The substrate processing apparatus 10 may be, for example, a semiconductor manufacturing apparatus, a heat treatment apparatus, or a film formation apparatus.

The substrate processing apparatus 10 receives, for example, control commands based on a recipe from the apparatus controller 12 and executes a process. The process includes a plurality of process steps. For example, the recipe is set to divide the process into a plurality of process steps (sections). The substrate processing apparatus 10 is equipped with a plurality of sensors, such as a temperature sensor for measuring temperature and a pressure sensor for measuring pressure.

The substrate processing apparatus 10 may include the apparatus controller 12, or may be communicably connected to the apparatus controller 12 without including the apparatus controller 12. The apparatus controller 12 illustrated in FIG. 1 is provided for each substrate processing apparatus 10, but may be provided for a plurality of substrate processing apparatuses 10.

The apparatus controller 12 outputs control commands to control components of the substrate processing apparatus 10 according to a recipe so as to cause the substrate processing apparatus 10 to execute a process including a plurality of process steps based on the recipe.

The apparatus controller 12 has a man-machine interface function for receiving instructions from an operator for the substrate processing apparatus 10 and providing information related to the substrate processing apparatus 10 to the operator. The apparatus controller 12 receives sensor values output from a plurality of sensors installed in the substrate processing apparatus 10. The sensors include a temperature sensor, a pressure sensor, and a flow rate sensor.

The apparatus controller 12 may store a process log for each execution of a process (hereinafter referred to as a “run”) performed according to a recipe. The process log includes the time taken for each process step (step time) executed in the substrate processing apparatus 10. The process log also includes, for example, the content of the recipe, sensor data of the substrate processing apparatus 10 information related toon of the process based on the recipe, and result data.

The server apparatus 16 may receive and store information related to a plurality of substrate processing apparatuses 10 in one or more manufacturing plants 2. For example, the server apparatus 16 receives and stores process logs of a plurality of substrate processing apparatuses 10 in one or more manufacturing plants 2.

The server apparatus 16 may have a man-machine interface function for providing information related to the substrate processing apparatus 10 to an operator using, for example, a web application. The server apparatus 16 may also have a man-machine interface function for displaying information related to a time-variable step, which will be described later, using, for example, a web application.

The operator terminal 18 may receive and store information related to a plurality of substrate processing apparatuses 10 in one or more manufacturing plants 2. For example, the operator terminal 18 receives and stores process logs of a plurality of substrate processing apparatuses 10 in one or more manufacturing plants 2. The operator terminal 18 may have a man-machine interface function for displaying information related to the substrate processing apparatus 10 using, for example, a web application. The operator terminal 18 may also have a man-machine interface function for displaying information related to a time-variable step, which will be described later, using, for example, a web application.

The apparatus controller 12 and the server apparatus 16 may cause the operator terminal 18 to display information related to the substrate processing apparatus 10 and information related to a time-variable step, which will be described later. The apparatus controller 12, the server apparatus 16, and the operator terminal 18 illustrated in FIG. 1 are examples of information processing devices according to the present embodiment.

The substrate processing system 1 illustrated in FIG. 1 is an example, and various system configurations are of course possible depending on the application and purpose. The classification of devices such as the apparatus controller 12, the server apparatus 16, and the operator terminal 18 illustrated in FIG. 1 is also merely an example. For example, various configurations are possible, such as a configuration in which at least two of the apparatus controller 12, the server apparatus 16, and the operator terminal 18 are integrated, or a configuration in which they are further divided.

### <Hardware Configuration>

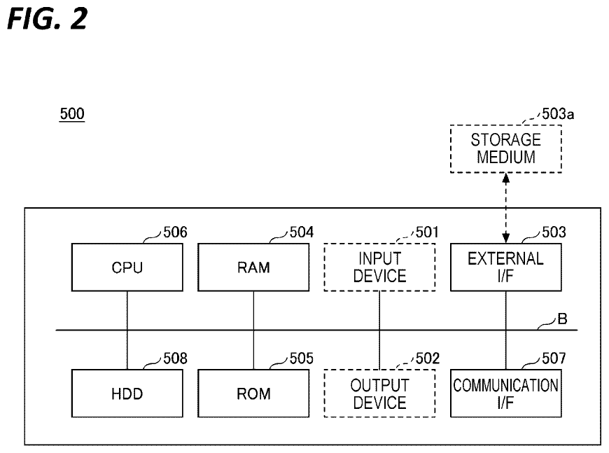

The apparatus controller 12, the server apparatus 16, and the operator terminal 18 of the substrate processing system 1 illustrated in FIG. 1 are implemented by a computer (information processing apparatus) having a hardware configuration such as that illustrated in FIG. 2. FIG. 2 is a hardware configuration diagram illustrating an example of a computer.

The computer 500 in FIG. 2 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, all of which are interconnected via a bus B. The input device 501 and the output device 502 may be configured to be connected and used when necessary.

The input device 501 includes, for example, a keyboard, a mouse, or a touch panel, and is used by an operator to input various operation signals. The output device 502 is, for example, a display, and is used to present processing results from the computer 500. The communication I/F 507 is an interface for connecting the computer 500 to the network 20 or 22. The HDD 508 is an example of a non-volatile storage device that stores programs and data.

The external I/F 503 functions as an interface with external devices. The computer 500 may read from and/or write to a recording medium 503a, such as a secure digital (SD) memory card, via the external I/F 503. The ROM 505 is an example of a non-volatile semiconductor memory (storage device) in which programs and data are stored. The RAM 504 is an example of a volatile semiconductor memory (storage device) that temporarily stores programs and data.

The CPU 506 is a processor that reads programs and data from storage devices such as the ROM 505 and the HDD 508 onto the RAM 504 and executes processes to implement overall control and functions of the computer 500.

The apparatus controller 12, the server apparatus 16, and the operator terminal 18 in FIG. 1 may implement various functions described later by executing programs on the computer 500 having the hardware configuration illustrated in FIG. 2.

### <Functional Configuration>

In the following, an example in which the information processing apparatus that processes process logs of one or more substrate processing apparatuses 10 is the operator terminal 18 will be described. The information processing apparatus that processes the process logs of one or more substrate processing apparatuses 10 may also be the apparatus controller 12 or the server apparatus 16.

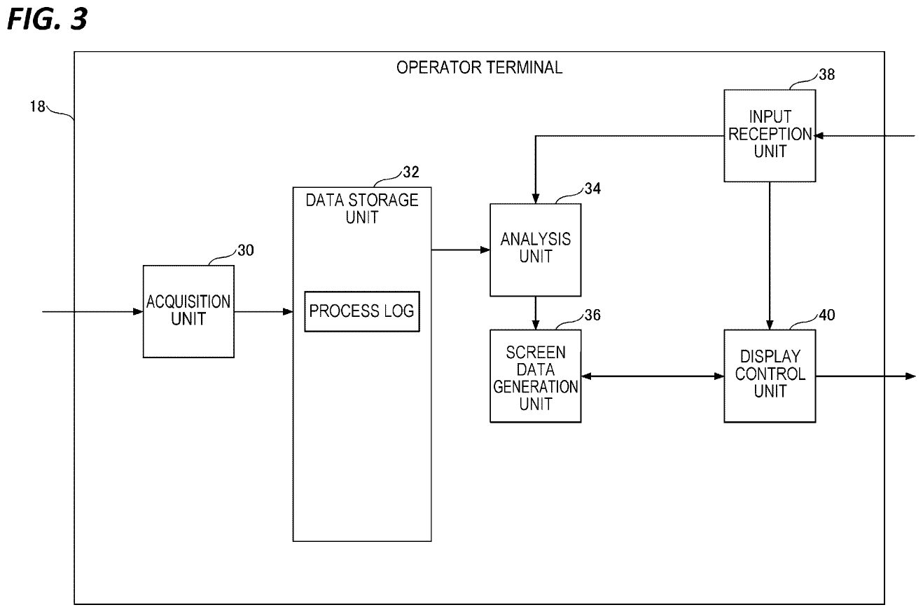

The operator terminal 18 of the substrate processing system 1 according to the present embodiment is implemented, for example, using the functional blocks illustrated in FIG. 3. FIG. 3 is a functional block diagram illustrating an example of the operator terminal 18 according to the present embodiment. Components not necessary for the description of the present embodiment are omitted from the diagram in FIG. 3.

The operator terminal 18 illustrated in FIG. 3 implements a data acquisition unit 30, a data storage unit 32, an analysis unit 34, a screen data generation unit 36, an input reception unit 38, and a display control unit 40 by executing a program for the operator terminal 18.

The data acquisition unit 30 acquires process logs for each run of one or more substrate processing apparatuses 10 that have executed the same process including a plurality of process steps according to a recipe. The data acquisition unit 30 may acquire the process logs of the substrate processing apparatuses 10 from the substrate processing apparatuses 10, the apparatus controller 12, or the server apparatus 16. The process logs of the substrate processing apparatuses 10 acquired by the data acquisition unit 30 include, for example, the step times for each run of one or more substrate processing apparatuses 10 that have executed the process according to the recipe. The data acquisition unit 30 stores the acquired process logs of the substrate processing apparatuses 10 in the data storage unit 32.

The input reception unit 38 receives various operations from an operator. For example, the operations received from the operator may include, for example, an application startup operation and various operations performed on the started application. The input reception unit 38 notifies the analysis unit 34 and the display control unit 40 of the content of the various operations received from the operator.

The analysis unit 34 compares, based on the process logs for each run of the substrate processing apparatuses 10 stored in the data storage unit 32, step times taken for the same process step, and analyzes process steps having time variations as time-variable steps.

The step times taken for the same process step may be those of different runs included in the process logs of a single substrate processing apparatus 10. Alternatively, the step times taken for the same process step may be those included in the process logs of a plurality of substrate processing apparatuses 10.

The step times taken for the same process step, included in the process logs of substrate processing apparatuses 10 that have executed the same process according to a recipe, are the same as or similar to each other unless there are factors such as machine differences, failures, or malfunctions. Therefore, the analysis unit 34 analyzes process steps having variations in step time (having time variations) as time-variable steps by comparing the step times taken for the same process step, based on the process logs for each run of one or more substrate processing apparatuses 10.

The analysis unit 34 may analyze that the process steps having time variations is time-variable steps when the difference in step time for the same process step is equal to or greater than a predetermined time. A time-variable step may be, for example, a process step that is completed when the situation of a substrate processing apparatus 10 reaches a specific condition after an execution has been initiated according to the recipe.

Process steps that are completed when the situation of the substrate processing apparatus 10 reaches a specific condition include, for example, a step of waiting for vacuuming, a step of waiting for temperature stabilization, a step of waiting for pressure stabilization, or a step of waiting for cooling of a wafer to a predetermined temperature.

The screen data generation unit 36 generates screen data including information related to the time-variable steps, based on the analysis result by the analysis unit 34. The display control unit 40 causes the screen data including information related to the time-variable steps to be displayed on the output device 502.

For example, the display control unit 40 collects the step times taken for the time-variable steps for each run and displays them, in a manner that allows comparison. The display control unit 40 may collect the step times taken for the time-variable steps for each time-variable step and displays them, in a manner that allows comparison. The display control unit 40 may display the distribution of the step times taken for the time-variable steps for each time-variable step and each substrate processing apparatus 10, in a manner that allows comparison. Examples of screen images displayed on the output device 502 by the display control unit 40 will be described later.

The functional block diagram in FIG. 3 is an example. At least a portion of the functional blocks in FIG. 3 may be provided in a computer 500 other than the operator terminal 18. For example, the data storage unit 32, the analysis unit 34, and the screen data generation unit 36 may be provided in the server apparatus 16 or the apparatus controller 12.

### <Processing>

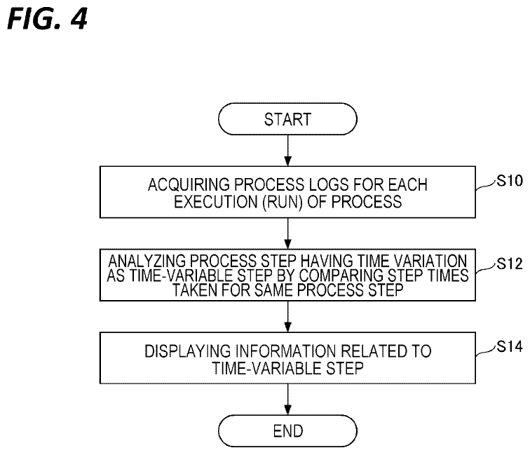

The substrate processing system 1 of the present embodiment processes process logs of one or more substrate processing apparatuses 10 and displays information related to time-variable steps, for example, in the procedure illustrated in FIG. 4. FIG. 4 is a flowchart illustrating an example of a processing procedure for displaying information related to time-variable steps in the substrate processing system 1 of the present embodiment. The processing illustrated in the flowchart of FIG. 4 may be performed by the apparatus controller 12, by the substrate processing apparatus 10 equipped with the apparatus controller 12, by the server apparatus 16, or by the operator terminal 18. Here, an example in which the processing is performed by the operator terminal 18 illustrated in FIG. 3 is described.

In step S10, the data acquisition unit 30 of the operator terminal 18 acquires process logs for each run of one or more substrate processing apparatuses 10 that have executed the same process including a plurality of process steps according to a recipe, and stores them in the data storage unit 32.

In step S12, the analysis unit 34 of the operator terminal 18 reads the process logs for each run of the substrate processing apparatuses 10 stored in the data storage unit 32. Based on the retrieved process logs, the analysis unit 34 compares the step times taken for the same process step and analyzes process steps having time variations as time-variable steps.

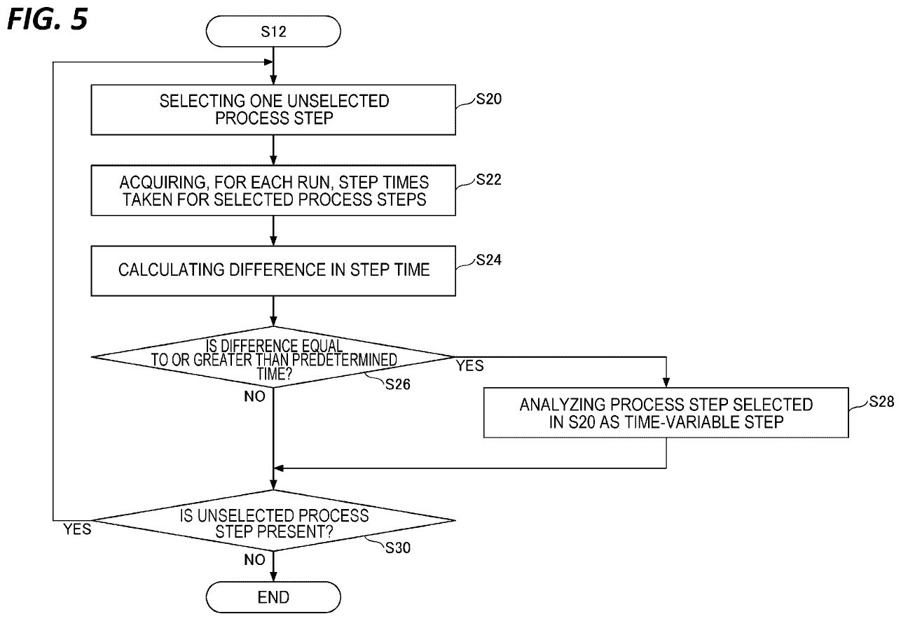

The processing of step S12 is performed, for example, according to the procedure illustrated in FIG. 5. FIG. 5 is a flowchart illustrating an example of the processing procedure of step S12.

In step S20, the analysis unit 34 selects one unselected process step from the process logs acquired in step S10. The process logs acquired in step S10 are process logs for each run of one or more substrate processing apparatuses 10 that have executed the same process according to a recipe.

In step S22, the analysis unit 34 acquires, for each run, the step times taken for the process steps selected in step S20 from the process logs for each run of one or more substrate processing apparatuses 10.

In step S24, the analysis unit 34 compares the step times for each run acquired in step S22 and calculates a difference in step time. For example, the analysis unit 34 may calculate a difference between the maximum value and the minimum value of the step times acquired in step S22 as the difference in step time. Another calculation method may be used to calculate the difference in step time.

In step S26, the analysis unit 34 determines whether the difference in step time calculated in step S24 is equal to or greater than a predetermined time (e.g., 5 seconds). When the difference in step time calculated in step S24 is equal to or greater than the predetermined time, the analysis unit 34 performs the processing in step S28. In step S28, the analysis unit 34 analyzes the single process step selected in step S20 as a time-variable step. When the difference in step time calculated in step S24 is less than the predetermined time, the analysis unit 34 skips the processing in step S28.

In step S30, the analysis unit 34 determines whether there is an unselected process step in the process logs acquired in step S10. When there is an unselected process step in the process logs acquired in step S10, the analysis unit 34 returns to the processing of step S20. When there is no unselected process step in the process logs acquired in step S10, the analysis unit 34 terminates the processing of the flowchart illustrated in FIG. 5.

According to the flowchart of FIG. 5, from among the process steps included in the process logs acquired in step S10, a process step having a step time difference equal to or greater than a predetermined time may be analyzed (selected) as a time-variable step.

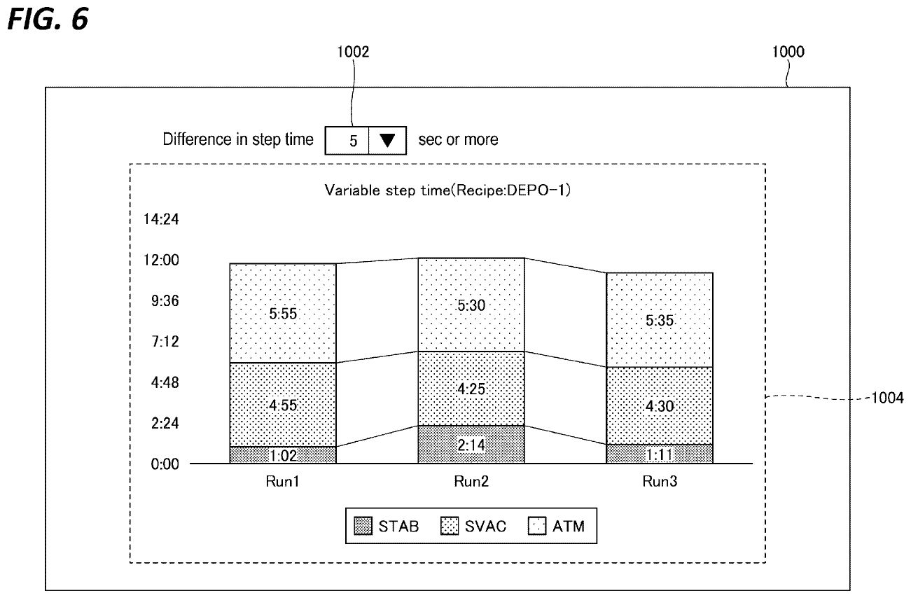

Returning to step S14 in FIG. 4, the screen data generation unit 36 generates screen data including information related to the time-variable step selected in step S12. The display control unit 40 causes the screen data including the information related to time-variable steps to be displayed on the output device 502, for example, as illustrated in FIGS. 6 to 9.

FIG. 6 is a view illustrating an example of a screen image including information related to time-variable steps. A screen 1000 illustrated in FIG. 6 is an example of a screen that displays the step times taken for time-variable steps, which are collected for each run, in a manner that allows comparison. The screen 1000 includes a difference setting field 1002 for a predetermined time used in step S26 of FIG. 5, and a display field 1004 for displaying the step times taken for the time-variable steps, which are collected for each run, in a manner that allows comparison.

The display field 1004 illustrates an example in which the time-variable steps selected in step S12 are “STAB,” “SVAC,” and “ATM.” The display field 1004 displays the step times taken for the time-variable steps “STAB,” “SVAC,” and “ATM” as a stacked bar graph for each of “Run 1,” “Run 2,” and “Run 3.” The time-variable steps may include at least one of: a transfer time required for transferring wafers from a sealed storage container (FOUP) to a boat in the substrate processing apparatus 10; a time until the temperature becomes stable after loading the boat into the processing container; a time required to reduce the pressure inside the processing container from atmospheric pressure to a process pressure; and a time required to increase the temperature inside the processing container from a loading temperature to a process temperature.

According to the screen 1000 of FIG. 6, the time-variable steps selected from the process steps included in the process logs may be visualized and displayed for each run to allow comparison. In addition, the screen 1000 of FIG. 6 may be visualized and displayed so as to allow comparison of time-variable steps of runs executed at different times. By referring to the screen 1000 in which the time-variable steps of runs executed at different times are visualized for comparison, an operator may identify the times at which the time-variable steps occurred.

In addition, by referring to the display field 1004 of FIG. 6, an operator may identify the time-variable steps. The operator may also compare the step times of the time-variable steps for each run. Furthermore, the operator may compare the total step times of the time-variable steps for each run.

As a result, by referring to the display field 1004, the operator may easily identify the time-variable steps, and it becomes easier to identify components to be adjusted in the substrate processing apparatus 10 according to the time-variable steps.

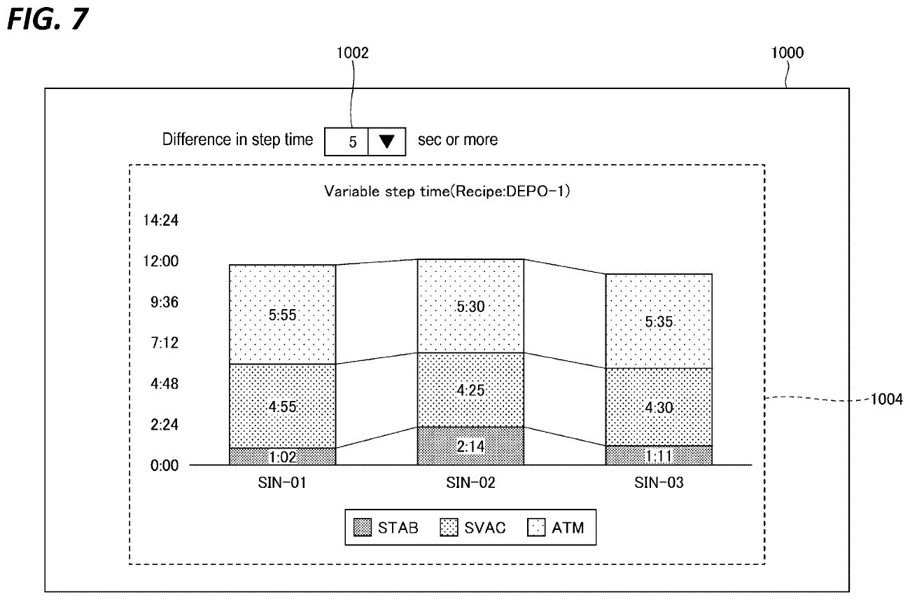

FIG. 7 is an example of a screen image including information related to time-variable steps. A screen 1000 illustrated in FIG. 7 is an example of a screen that displays the step times taken for time-variable steps, which are collected for each substrate processing apparatus 10, in a manner that allows comparison. The screen 1000 of FIG. 7 includes a difference setting field 1002 for a predetermined time used in step S26 of FIG. 5, and a display field 1004 for displaying the step times taken for the time-variable steps, which are collected for each substrate processing apparatus 10, in a manner that allows comparison.

The display field 1004 illustrates an example in which the time-variable steps selected in step S12 are “STAB,” “SVAC,” and “ATM.” The display field 1004 displays the step times taken for the time-variable steps “STAB,” “SVAC,” and “ATM” as a stacked bar graph for each of the substrate processing apparatuses “SIN-01,” “SIN-02,” and “SIN-03.” “SIN-01,” “SIN-02,” and “SIN-03” are examples of identification information used to identify the substrate processing apparatuses 10.

According to the screen 1000 of FIG. 7, the time-variable steps selected from the process steps included in the process logs may be visualized and displayed for each substrate processing apparatus 10 to allow the time-variable steps to be compared among the substrate processing apparatuses 10. In addition, by referring to the display field 1004 of FIG. 7, an operator may identify the time-variable steps. The operator may also compare the step times of the time-variable steps among the substrate processing apparatuses 10. Furthermore, the operator may compare the total step times of the time-variable steps among the substrate processing apparatuses 10.

As a result, by referring to the display field 1004 of FIG. 7, the operator may easily identify the time-variable steps while comparing the step times of the time-variable steps among the substrate processing apparatuses 10. In addition, by referring to the display field 1004 of FIG. 7, the operator may easily recognize the substrate processing apparatus 10 that has the shortest step time for the time-variable steps.

The substrate processing apparatus 10 having the shortest step time for the time-variable steps exhibits higher productivity than the other substrate processing apparatuses 10. Accordingly, the operator may improve the productivity of the plurality of substrate processing apparatuses 10 executing the same process according to the recipe by adjusting the other substrate processing apparatuses 10 so as to reduce the difference from the substrate processing apparatus 10 having the shortest step time for the time-variable steps.

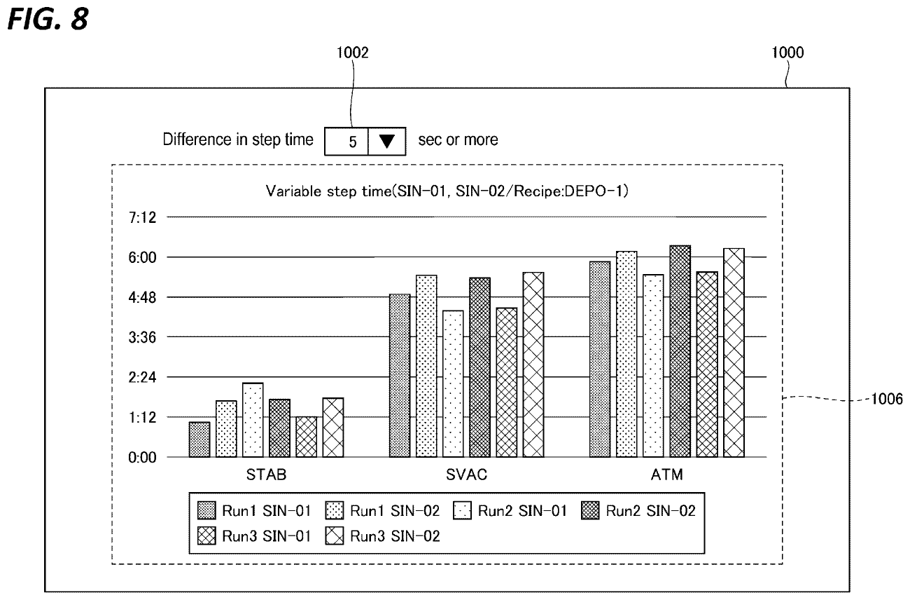

FIG. 8 is an example of a screen image including information related to time-variable steps. A screen 1000 illustrated in FIG. 8 is an example of a screen that displays the step times taken for time-variable steps, which are collected for each type of time-variable step, in a manner that allows comparison.

The screen 1000 of FIG. 8 includes a difference setting field 1002 for a predetermined time used in step S26 of FIG. 5, and a display field 1006 for displaying the step times taken for the time-variable steps, which are collected for each type of time-variable step, in a manner that allows comparison.

The display field 1006 of FIG. 8 illustrates an example in which the types of time-variable steps selected in step S12 are “STAB,” “SVAC,” and “ATM.” The display field 1006 also displays the step times for the time-variable step types “STAB,” “SVAC,” and “ATM” as bar graphs for each run of the substrate processing apparatuses “SIN-01,” “SIN-02,” and “SIN-03.”

According to the screen 1000 of FIG. 8, time-variable steps selected from the process steps included in the process logs may be visualized and displayed for each type of time-variable step to allow the time-variable steps specified by respective runs and substrate processing apparatuses 10 to be compared. In addition, by referring to the display field 1006 of FIG. 8, an operator may identify combinations of substrate processing apparatus 10 and runs having shorter step times for each type of time-variable step.

As a result, by referring to the display field 1006 of FIG. 8, the operator may easily identify the time-variable steps while comparing the step times of the time-variable steps among combinations of substrate processing apparatuses 10 and runs. In addition, by referring to the display field 1006 of FIG. 8, the operator may easily recognize the combination of substrate processing apparatus 10 and run having the shortest step time for the time-variable steps.

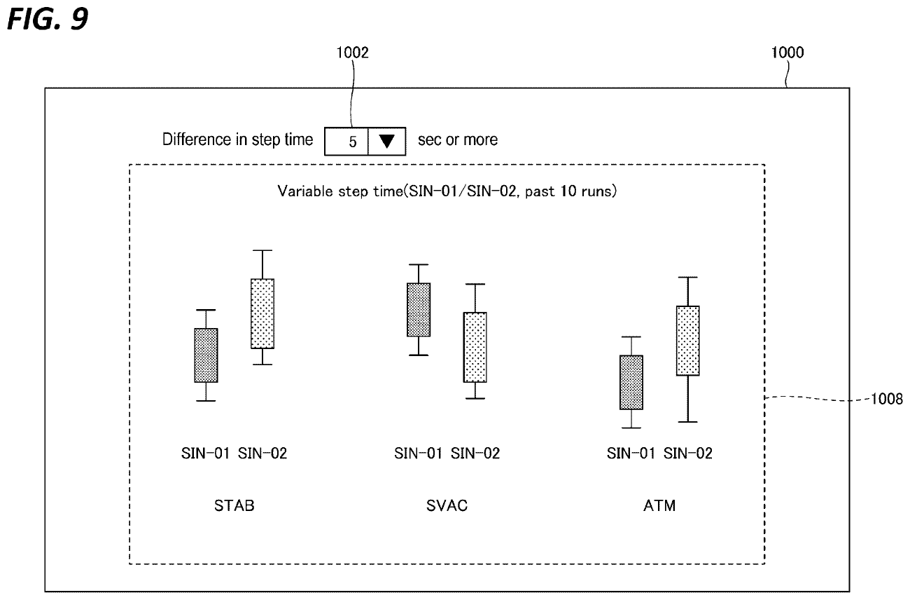

FIG. 9 is an example of a screen image including information related to time-variable steps. A screen 1000 illustrated in FIG. 9 is an example of a screen that displays a distribution of the step times taken for time-variable steps, in a manner that allows comparison for each type of time-variable step and each substrate processing apparatus 10.

The screen 1000 of FIG. 9 includes a difference setting field 1002 for a predetermined time used in step S26 of FIG. 5, and a display field 1008 for displaying the distribution of the step times taken for the time-variable steps, in a manner that allows comparison for each type of time-variable step and each substrate processing apparatus 10.

The display field 1008 of FIG. 9 illustrates an example in which the types of time-variable steps selected in step S12 are “STAB,” “SVAC,” and “ATM.” The display field 1008 also displays the step times of the time-variable step types “STAB,” “SVAC,” and “ATM” as box-and-whisker plots for the respective substrate processing apparatuses “SIN-01” and “SIN-02.” The box-and-whisker plots in FIG. 9 graphically represent the distribution of the step times for the time-variable steps based on the maximum value, minimum value, and quartiles thereof.

According to the screen 1000 of FIG. 9, the distribution of the step times of the time-variable steps may be visualized and displayed for each type of time-variable step and each substrate processing apparatus 10, in a manner that allows comparison of the distributions of the step times of the time-variable steps, for example, over the past ten runs of the substrate processing apparatuses 10.

As a result, by referring to the display field 1008 of FIG. 9, the operator may easily compare the distributions of the step times of the time-variable steps across the types of time-variable steps and the substrate processing apparatuses 10. For example, by referring to the display field 1008 of FIG. 9, the operator may identify a substrate processing apparatus 10 having good performance for each type of time-variable step and may adjust other substrate processing apparatuses 10 so as to reduce the difference from the identified substrate processing apparatus 10.

The operator may use the screens 1000 illustrated in FIGS. 6 to 9, for example, to improve the productivity of the substrate processing apparatuses 10 that perform mass production using the same process and recipe. In addition, the operator may use the screens 1000 illustrated in FIGS. 6 to 9, for example, for startup inspections when adding a new substrate processing apparatus 10 to a plurality of substrate processing apparatuses 10 that are already performing mass production using the same process and recipe. In addition, the screens 1000 of FIGS. 6 to 9 may be configured to display all of the time-variable steps, or to display only a portion of the time-variable steps selected from the entire set of time-variable steps. For example, when there are a large number of time-variable steps, the display may be limited to time-variable steps ranked in a predetermined order (e.g., the top 10) in terms of step time length, and only those time-variable steps may be displayed.

The present embodiment may provide a technique that may facilitate identification of process steps having time variations from process logs of one or more substrate processing apparatuses 10 that have executed the same process.

According to the present disclosure, it may be possible to facilitate identification of process steps having time variations from process logs of one or more substrate processing apparatuses that have executed the same process.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. An information processing apparatus comprising:
acquisition circuitry configured to acquire a process log for each execution of a process including a plurality of process steps in one or more substrate processing apparatuses that execute the process according to a recipe;
analysis circuitry configured to compare, based on the process logs, step times taken for the same process step and analyze a process step having time variation as a time-variable step; and
display control circuitry configured to display information related to the time-variable step.

2. The information processing apparatus of claim 1, wherein the analysis circuitry are configured to analyze the process step having the time variation as the time-variable step when a difference in step time taken for the same process step is equal to or greater than a predetermined time.

3. The information processing apparatus of claim 1, wherein the display control circuitry are configured to collect and display the step time taken for the time-variable step for each execution of the process, in a manner that allows comparison.

4. The information processing apparatus of claim 1, wherein the display control circuitry are configured to collect and display the step time taken for the time-variable step for each of the one or more substrate processing apparatuses, in a manner that allows comparison.

5. The information processing apparatus of claim 1, wherein the display control circuitry are configured to collect and display the step time taken for the time-variable step for each type of time-variable step, in a manner that allows comparison.

6. The information processing apparatus of claim 1, wherein the display control circuitry is configured to display a distribution of the step times taken for the time-variable step for each type of time-variable step and each of the one or more substrate processing apparatuses, in a manner that allows comparison.

7. The information processing apparatus of claim 1, wherein each time-variable step is a process step that is completed when a situation of a corresponding one of the substrate processing apparatuses reaches a predetermined condition after execution of the process has started in accordance with the recipe.

8. The information processing apparatus of claim 1, wherein each time-variable step includes at least one of:
a transfer time for transferring wafers from a sealed storage container to a boat in the substrate processing apparatus;
a time until temperature stabilization after the boat is loaded into a processing container;
a time required to reduce pressure in the processing container from atmospheric pressure to a process pressure; and
a time required to increase temperature in the processing container from a loading temperature to a process temperature.

9. An information processing method performed by an information processing apparatus, the information processing method comprising:
acquiring a process log for each execution of a process including a plurality of process steps in one or more substrate processing apparatuses that execute the process according to a recipe;
comparing, based on the process logs, step times taken for the same process step and analyzing a process step having time variation as a time-variable step; and
displaying information related to the time-variable step.

10. A substrate processing apparatus comprising:
acquisition circuitry configured to acquire a process long for each execution of a process including a plurality of process steps in one or more substrate processing apparatuses that execute the process according to a recipe;
analysis circuitry configured to compare, based on the process logs, step times taken for the same process step and analyze a process step having time variation as time-variable step; and
display control circuitry configured to display information related to the time-variable step.
